(19) United States
(12) Patent Application Publication
(10) Pub. No.: US 2006/0006533 A1
(43) Pub. Date: Jan. 12, 2006

(54) Motherboard structure for preventing short circuit

(75) Inventors: Yi-Chun Wang, Shenzhen (CN); Jing Li, Shenzhen (CN); Yang-Zi Liu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/176,054

(22) Filed: Jul. 7, 2005

(30) Foreign Application Priority Data
Jul. 12, 2004 (CN) 200410028138.9

(51) Int. Cl. H01L 21/44; H01L 23/48

(52) U.S. Cl. 257/737; 438/613; 257/778; 438/108; 257/786; 438/612

(57) ABSTRACT

A motherboard for preventing short circuit includes an IC device and a PCB. The IC device has a plurality of tin balls, and the PCB has matching pads with the tin balls of the IC device. The tin balls and the pads knit together to mount the IC device to the PCB. A silk screen is printed on a surface of the PCB, and an additional silk screen is printed on the silk screen where there is no pads formed for preventing short circuit. Because printing silk screen is a necessary step of printed circuit board manufacturing, so the motherboard for preventing short circuit has no need to add additional step to printed circuit board manufacturing.

### BACKGROUND OF THE INVENTION

### FIELD OF THE INVENTION

The present invention relates to motherboard structures, and particular to a motherboard for preventing shot circuit between two adjacent tin balls of an IC device during solder reflow process.

### GENERAL BACKGROUND

It has been a trend in the field of making semiconductor devices to increase the packing density of a silicon wafer. IC designers are continuously tempted to scale down the size of each device and increase chip level integration at an even faster pace. Further, the manufacturers of the devices are striving to reduce the sizes while simultaneously increasing their speed. A plurality of ball-grid array tin balls is formed on the rear surface of a conventional BGA IC device. Since the BGA IC device is used in coordination with surface-mount technology (SMT) where tin balls are utilized for connection with a printed circuit board (PCB) instead of pins, requirements for packaging become stricter. The SMT is a method to mount a BGA IC device on a PCB. Then, a nitrogen solder reflow treatment is performed to melt the tin balls beneath the BGA IC device, making the BGA IC device and the PCB knitted together to form a functional system. At this time, if solder spills out from the connection points, a short circuit between two adjacent tin balls will occur.

Referring to FIGS. 1 and 2, a motherboard includes a PCB 100 and an IC device 500. The PCB 100 has an array 30 of a plurality of pads 400 for mounting the IC device 500 thereon. The IC device 500 is a BGA-type IC chip with a plurality of tin balls 700 formed on a bottom surface. FIG. 1 shows a part of the pads array 300 of the PCB 100, in fact, the number of the pads is more than shown. For example, an Intel's Pentium 4 processor has 478 tin balls and the PCB has the matching pads to accept them.

The IC device 500 is mounted directly onto the PCB 100 using standard surface mount technology equipment. A nitrogen solder reflow treatment is performed to melt the tin balls 700 to make the tin balls 700 of the IC device 500 and the pads 400 of the PCB 100 knitted together. The PCB 100 is manufactured with a solder mask 800 that covers foils except in the places where the designers do not want them to be soldered. A silk screen 200 is printed on a top of the solder mask 800 and has a similar height to pads 400 extending from the upper face of the PCB 100. Text and symbols are printed on the PCB 100 to label the locations for the different components that are to be mounted. The solder mask 800 is an insulating and protective coat that protects thin copper wires and prevents solder from attaching outside the connection points. Sometimes if the solder overflowed 720 from the connected point beyond the limit that the solder mask 800 resist, a short circuit between two adjacent tin balls 410, 430 of the IC 500 will occur.

U.S. Pat. No. 6,239,383 disclosed a ball-grid array BGA IC device for preventing short circuits. A plurality of supporting pads is formed on a rear surface of a BGA IC device where tin balls are located. The melting point of the supporting pads is higher than that of the ball-grid array tin balls. The supporting pads are made of aluminum with a higher melting point and good heat conducting. The BGA IC device can be supported by the supporting pads when the tin balls are melted during a nitrogen solder reflow treatment, thereby preventing short circuits. Moreover, due to the supporting pads with a higher melting point than the tin balls, the supporting pads are never melted during the nitrogen solder reflow treatment. However, packaging technology demands that the ICs equip with more tin balls for connection, and meanwhile, available space for mounting those additional tin balls is shrinking, it is therefore difficult to form the supporting pads on the surface of the BGA IC device.

What is needed is a motherboard structure for preventing shot circuit during solder reflow process.

### SUMMARY

A motherboard for preventing short circuit includes an IC device and a PCB. The IC device has a plurality of tin balls, and the PCB has matching pads with the tin balls of the IC device. The tin balls and the pads knitted together to mount the IC device to the PCB. A silk screen is printed on a surface of the PCB, and an additional silk screen is printed on the silk screen where there is no pads formed for preventing short circuit by forming retaining holes above pads to retain the tin balls.

It is of advantage that printing silk screen is a necessary step of printed circuit board manufacturing, so the motherboard for preventing short circuit has no need to add additional step to printed circuit board manufacturing. The additional silk screen can retain more solder than conventional PCB when the tin balls are melted during a solder reflow treatment, thereby preventing short circuits.

Other objects, advantages and novel features will become more apparent from the following detailed description when taken in conjunction with the accompanying drawings, in which:

### BRIEF DESCRIPTION OF THE DRAWINGS

FIG. 1 is a top view of pad arrays of a conventional PCB; and

FIG. 2 is a section view showing a short circuit between tin balls of a conventional IC;

FIG. 3 is a bottom view of a PCB in according with a preferred embodiment of the present invention with an additional silk screen formed thereon; and

FIG. 4 is a section view of the PCB of FIG. 3 together with an IC mounted thereon.

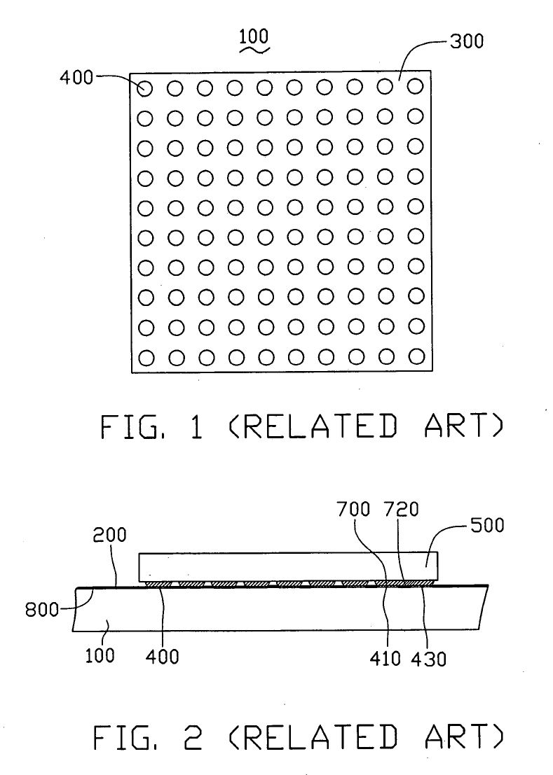

### DETAILED DESCRIPTION OF THE EMBODIMENT

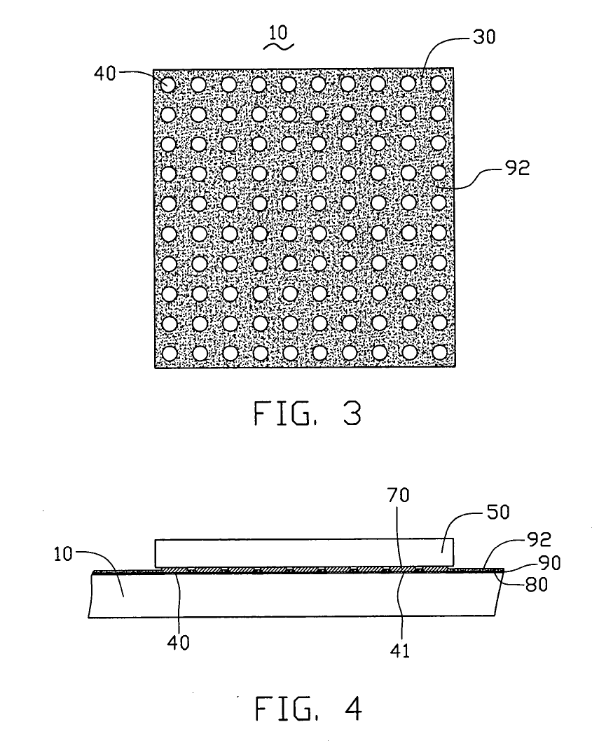

Referring to FIGS. 3 and 4, a motherboard includes a printed circuit board (PCB) 10 and an electronic device like an integrated circuit (IC) device 50. The PCB 10 has a plurality of pads array 30 for mounting the IC device 50 thereon. The IC device 50 is an IC of BGA-type with a plurality of solder means, for example tin balls 70, formed on a bottom surface thereof. A solder mask 80 that covers foils except in the places where the designers do not want it to be soldered is formed on the PCB 10. A non-solderable screen, for example a silk screen 90, is printed on a top of the solder mask 80. Among the pads array 30, an additional part of the non-solderable screen, i.e. an additional silk screen 92, is printed in the places where there are no pads 40. The additional silk screen 92 also has the features of insulating and resisting solder. A total thickness of the solder mask 80, the silk screen 90 and the additional silk screen 92 is greater than the solder mask and the silk screen of a conventional PCB so that a significant retaining hole is formed right above each pad 40 of the PCB 10 due to difference of the total thickness. When the IC device 50 is mounted on the PCB 10, if a little of solder is overflowed from the connected point, the additional silk screen 92 can retain more solder than the conventional PCB as shown in FIG. 2. That is, The PCB 10 has the additional silk screen 92 formed on the top of the silk screen 90 according to the embodiment of the present invention can provide additional protection function to the PCB 10 for preventing short circuits.

In addition, silk screen printing is accomplished with traditional silk-screen technology. This process is necessary in making a PCB, so it is no need to add additional making process to make the motherboard.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A motherboard for preventing short circuit comprising:
an IC device, the IC device having a plurality of tin balls;
a printed circuit board (PCB) having matching pads with said tin balls of the IC device, the tin balls and the pads knitted together to mount the IC device to the PCB, a silk screen printed on a surface of the PCB; and
an additional silk screen printed on the silk screen where there is no pads formed.

2. The motherboard for preventing short circuit as claimed in claim 1, wherein the IC device is a BGA-type IC chip.

3. The motherboard structure for preventing short circuit as claimed in claim 1, wherein the silk screen is made by insulating and solder resisting material.

4. A method of making a motherboard with short circuit protection, an IC device having a plurality of tin balls mounted on the motherboard, the method comprising the following steps:
providing a PCB having an upper surface with a pads array formed thereon;
providing a solder mask on the surface of the PCB except the pads;
printing a silk screen on the solder mask; and
printing an additional silk screen on the silk screen except the pads.

5. The method of making a motherboard with short circuit protection as claimed in claim 4, wherein the IC device is a BGA-type chip.

6. The method of making a motherboard with short circuit protection as claimed in claim 4, wherein the silk screen is made by insulating and solder resisting material.

7. The method of making a motherboard with short circuit protection as claimed in claim 4, wherein the IC device is mounted on the PCB by SMT equipment.

8. A method for preparing a printed circuit board (PCB) readily to electrically connect with an electronic device, the method comprising the steps of:
forming a solder mask on said PCB to exclusively expose pads of said PCB for electrical connection with said electronic device;
forming a non-solderable screen, extending farther away from said PCB than said pads, on said solder mask to exclusively expose said pads in cooperation with said solder mask and acquire a retaining hole beside each of said pads; and
placing a solder means in said retaining hole between said each of said pads and said electronic device for further treatment to acquire said electrical connection between said PCB and said electronic device.

9. The method as claimed in claim 8, wherein said non-solderable screen is printed twice on said solder mask in said screen-forming step.

10. The method as claimed in claim 9, wherein said non-solderable screen is a silk screen and an additional silk screen is formed in a second printing process.

11. The method as claimed in claim 8, wherein said further treatment is a solder reflow process for heating said solder means.
